(19) United States
(12) Patent Application Publication
(10) Pub. No.: US 2026/0114043 A1
(43) Pub. Date: Apr. 23, 2026

(54) STACKED SEMICONDUCTOR DEVICE INCLUDING MULTIPLE MIDDLE ISOLATION LAYERS

(71) Applicant: SAMSUNG ELECTRONICS CO.,LTD., Suwon-si (KR)

(72) Inventors: Junmo Park, Clifton Park, NY (US); Kang-ill Seo, Springfield, VA (US)

(73) Assignee: SAMSUNG ELECTRONICS CO., LTD., Suwon-si (KR)

(21) Appl. No.: 19/076,651

(22) Filed: Mar. 11, 2025

Related U.S. Application Data
(60) Provisional application No. 63/710,973, filed on Oct. 23, 2024.

(51) Int. Cl. H10D 84/85; H10D 84/01

(52) U.S. Cl. CPC H10D 84/856; H10D 84/0188; H10D 84/851

(57) ABSTRACT

Provided is a semiconductor device which includes: a 1^{st} channel structure; a 2^{nd} channel structure vertically above the 1^{st} channel structure; and a middle isolation structure including a plurality of middle isolation layers between the 1^{st} channel structure and the 2^{nd} channel structure, wherein the plurality of middle isolation layers are separated in a vertical direction.

### CROSS-REFERENCE TO RELATED APPLICATION

This application is based on and claims priority from U.S. Provisional Application No. 63/710,973 filed on Oct. 23, 2024 in the U.S. Patent and Trademark Office, the disclosure of which is incorporated herein in its entirety by reference.

### BACKGROUND

### 1. Field

Apparatuses and methods consistent with the disclosure relate to a stacked semiconductor device in which multiple middle isolation layers are formed to separate channel structures of a stacked semiconductor device.

### 2. Description of Related Art

A stacked semiconductor device has been introduced in response to increased demand for an integrated circuit having high device density and performance. The stacked semiconductor device may include a 1^{st} transistor at a 1^{st} level and a 2^{nd} transistor at a 2^{nd} level vertically above the 1^{st} level, where each of the two transistors may be a fin field-effect transistor (FinFET), a nanosheet transistor, a forksheet transistor, or any other type of transistor.

The FinFET has one or more horizontally arranged vertical fin structures as a channel structure of which at least three surfaces are surrounded by a gate structure, and the nanosheet transistor is characterized by one or more nanosheet layers, which are vertically stacked or arranged on a substrate, as a channel structure and a gate structure surrounding all four surfaces of each of the nanosheet layers. The nanosheet transistor is referred to as gate-all-around (GAA) transistor, or as a multi-bridge channel field-effect transistor (MBCFET). The forksheet transistor is a combination of two nanosheet transistors with an isolation wall therebetween. Nanosheet layers of each nanosheet transistor are formed at each side of the isolation wall and pass through a gate structure in parallel with the isolation wall.

In the stacked semiconductor device, a middle isolation layer or middle dielectric isolation (MDI) layer is formed between a channel structure of the 1^{st} transistor at the 1^{st} level and a channel structure of the 2^{nd} transistor at the 2^{nd} level to isolate these two channel structures, thereby also to isolate source/drain regions and gate structures of the two transistors. At least to enhance device isolation performance, a thick middle isolation layer is required between two channel structures of a stacked semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides a semiconductor device which is a stacked semiconductor device in which multiple middle isolation layers are formed between vertically-stacked channel structures so that the multiple middle isolation layers can form a thicker middle isolation structure to improve device performance.

According to an aspect of the disclosure, there is provided a semiconductor device which may include: a 1^{st} channel structure; a 2^{nd} channel structure vertically above the 1^{st} channel structure; and a middle isolation structure including a plurality of middle isolation layers between the 1^{st} channel structure and the 2^{nd} channel structure, wherein the plurality of middle isolation layers are separated in a vertical direction.

According to an aspect of the disclosure, there is provided a semiconductor device which may include: a 1^{st} channel structure; a 2^{nd} channel structure vertically above the 1^{st} channel structure; a plurality of gate structures; and a middle isolation structure having a thickness in a vertical direction which is greater than a length between two adjacent gate structures in a channel-length direction, each of the gate structures being a replacement of a dummy gate structure.

According to an aspect of the disclosure, there is provided a method of manufacturing a semiconductor device, which may include: forming a 1^{st} channel structure; forming a 2^{nd} channel structure vertically above the 1^{st} channel structure; and forming a middle isolation structure comprising a plurality of middle isolation layers between the 1^{st} channel structure and the 2^{nd} channel structure, wherein the plurality of middle isolation layers are formed to be separated in a vertical direction.

### BRIEF DESCRIPTION OF DRAWINGS

Example embodiments of the disclosure will be more clearly understood from the following detailed description taken in conjunction with the accompanying drawings.

FIGS. 1A-1D illustrate a stacked semiconductor device in which multiple middle isolation layers are formed to separate channel structures of two transistors formed at a 1^{st} level and a 2^{nd} level, respectively, according to one or more embodiments.

FIG. 2 illustrates a stacked semiconductor device in which multiple middle isolation layers are formed to separate channel structures of two transistors formed at a 1^{st} level and a 2^{nd} level, respectively, and source/drain regions are isolated from a gate structure through inner spacers, according to one or more embodiments.

FIGS. 3A-3H illustrate cross-section views of intermediate semiconductor devices after respective steps of manufacturing a stacked semiconductor device in which multiple middle isolation layers are formed to separate channel structures of two transistors formed at a 1^{st} level and a 2^{nd} level, respectively, according to one or more embodiments.

FIGS. 4A and 4B illustrate a flowchart of a method of manufacturing a stacked semiconductor device in which multiple middle isolation layers are formed to separate channel structures of two transistors formed at a 1^{st} level and a 2^{nd} level, respectively, according to one or more other embodiments.

FIG. 5 is a schematic block diagram illustrating an electronic device including a stacked semiconductor device in which multiple middle isolation layers are formed to separate channel structures of two transistors formed at a 1^{st} level and a 2^{nd} level, respectively, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, elements referred to as a “left” element and a “right” element” may be a “right” element and a “left” element when a device or structure including these elements are differently oriented. Thus, herein, a “left” element and a “right” element of a structure may also be referred to as a “1^{st}” element and a “2^{nd}” element, respectively, of the structure as long as their structural relationship is clearly understood in the context of the descriptions.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

In the descriptions herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain region, a silicide layer such as cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” pertains to electrical insulation or separation between structures, layers, components or regions in a corresponding device or structure.

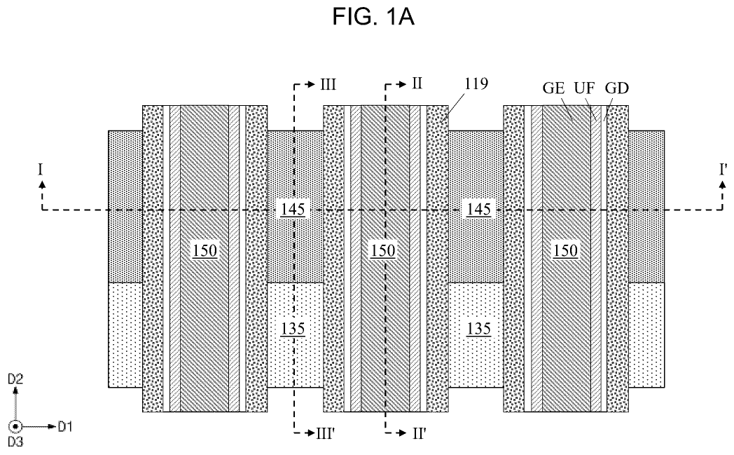

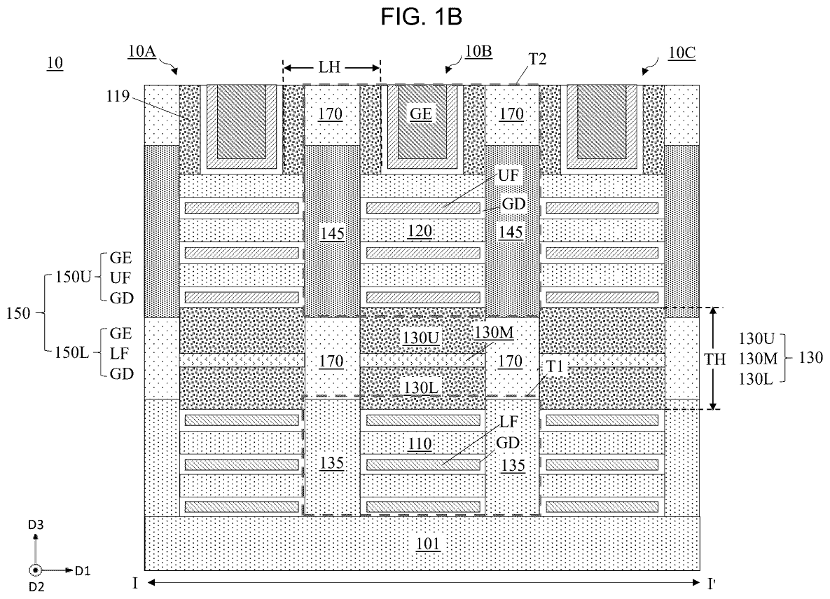

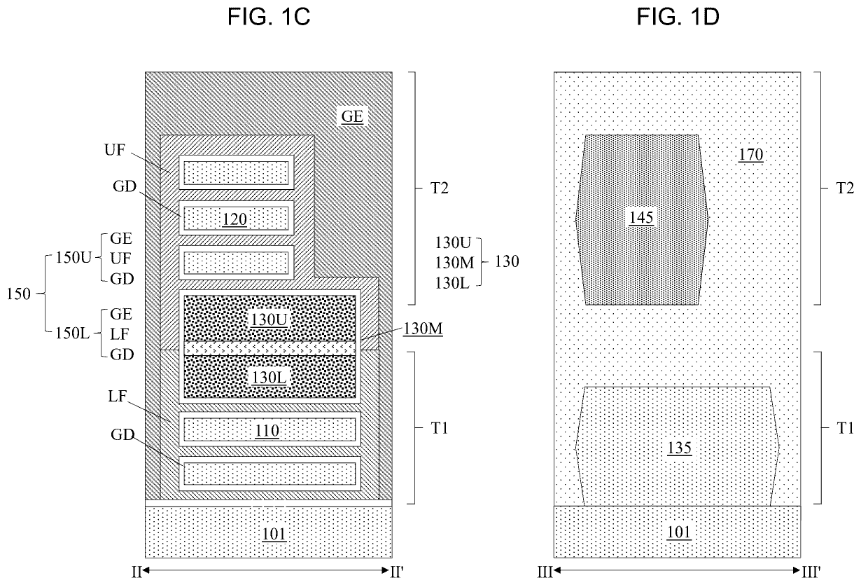

FIGS. 1A-1D illustrate a stacked semiconductor device in which multiple middle isolation layers are formed to separate channel structures of two transistors formed at a 1^{st} level and a 2^{nd} level, respectively, according to one or more embodiments.

FIG. 1A is a plan view of a stacked semiconductor device 10 and FIGS. 1B-1D are cross-section views of the stacked semiconductor device 10 shown in FIG. 1A taken along lines I-I′, II-II′ and III-III′, respectively. It is to be understood here that FIG. 1A is provided to show a positional relationship between gate structures and source/drain regions, and thus, some structural elements such as an interlayer isolation structure shown in FIGS. 1B-1D are omitted in FIG. 1A for brevity purposes.

As shown in FIG. 1A, a 1^{st} direction D1 is a channel-length direction in which current flows between two source/drain regions connected to each other through a channel structure, a 2^{nd} direction D2 is a channel-width direction or a cell-height direction that horizontally intersects the 1^{st} direction D1, and a 3^{rd} direction D3 is a channel-thickness direction that vertically intersects the 1^{st} direction D1 and the 2^{nd} direction D2. The 1^{st} direction D1 and the 2^{nd} direction D2 are referred to as horizontal directions, and the 3^{rd} direction D3 is referred to as a vertical direction.

Referring to FIGS. 1A-1D, the stacked semiconductor device 10 may include a 1^{st} channel stack 10A, a 2^{nd} channel stack 10B and a 3^{rd} channel stack 10C, each of which includes a 1^{st} channel structure formed of a plurality of 1^{st} channel layers 110 and a 2^{nd} channel structure formed of a plurality of 2^{nd} channel layers 120 vertically above the 1^{st} channel structure. The 1^{st} channel structure may be formed at a 1^{st} level on a substrate 101, and the 2^{nd} channel structure may be formed at a 2^{nd} level above the 1^{st} level. These channel layers 110 and 120 may be epitaxially grown from the substrate 101. Between the two channel structures may be formed a middle isolation structure 130 including a 1^{st} middle isolation layer 130L and a 2^{nd} middle isolation layer 130U with a gap layer 130M therebetween, which will be described later in detail.

The 1^{st} channel layers 110 may connect 1^{st} source/drain regions 135 at both sides thereof to each other so that current can flow therebetween at a control of a 1^{st} gate structure 150L which surrounds the 1^{st} channel layers 110. Similarly, the 2^{nd} channel layers 120 may connect 2^{nd} source/drain regions 145 at both sides thereof to each other so that current can flow therebetween at a control of a 2^{nd} gate structure 150U which surrounds the 2^{nd} channel layers 120. The 1^{st} gate structure 150L and the 2^{nd} gate structure 150U form a gate structure 150 of the stacked semiconductor device 10. The 1^{st} source/drain regions 135 may be epitaxially grown from the 1^{st} channel layers 110 of the 1^{st} channel structure in the channel stacks 10A-10C, and the 2^{nd} source/drain regions 145 may be epitaxially grown from the 2^{nd} channel layers 120 of the 2^{nd} channel structure in the channel stacks 10A-10C. The gate structure 150 may be formed by replacing a dummy gate structure and a plurality of sacrificial layers in a process of manufacturing the stacked semiconductor device 10.

Thus, in the stacked semiconductor device 10, the 1^{st} channel layers 110 along with the 1^{st} source/drain regions 135 at both sides thereof and the 1^{st} gate structure 150L surrounding these 1^{st} channel layers 110 may form a 1^{st} transistor T1, which is a nanosheet transistor, at the 1^{st} level. Further, the 2^{nd} channel layers 120 along with the 2^{nd} source/drain regions 145 at both sides thereof and the 2^{nd} gate structure 150U surrounding these 2^{nd} channel layers 120 may form a 2^{nd} transistor T2, which is also a nanosheet transistor, at the 2^{nd} level.

The substrate 101 may be a silicon (Si) substrate. Additionally, or alternatively, it may include other materials such as silicon germanium (SiGe), silicon carbide (SiC), not being limited thereto. The 1^{st} channel layers 110 and the 2^{nd} channel layers 120 may each be formed of silicon (Si) or silicon germanium (SiGe). The 1^{st} source/drain regions 135 and the 2^{nd} source/drain regions 145 may also be formed of Si or SiGe. However, when the 1^{st} source/drain regions 135 are formed of Si and doped with n-type impurities such as phosphorus (P), arsenic (As), antimony (Sb), etc., the 1^{st} transistor T1 may form an n-type transistor. In contrast, when the 2^{nd} source/drain regions 145 are formed of SiGe and doped with impurities such as boron (B), gallium (Ga), indium (In), etc., the 2^{nd} transistor T2 may form a p-type transistor. However, the disclosure is not limited thereto. Each of the 1^{st} transistor T1 and the 2^{nd} transistor T2 may be either p-type or n-type, according to one or more other embodiments.

The 1^{st} gate structure 150L of the 1^{st} transistor T1 may include a gate dielectric layer GD, a 1^{st} work-function metal layer LF and a gate electrode GE, and the 2^{nd} gate structure 150U may include the gate dielectric layer GD, a 2^{nd} work-function metal layer UF and the gate electrode GE.

The gate dielectric layer GD may include an interfacial layer and a high-k dielectric layer formed on the interfacial layer. The interfacial layer may be formed on each of the channel layers 110 and 120 to protect the channel layers 110 and 120 and facilitate growth of the high-k dielectric layer thereon, and the high-k dielectric layer may be formed on the interfacial layer to allow an increased gate capacitance without associated current leakage from the gate structure 150. For these purposes, the interfacial layer may be formed of an oxide material such as silicon oxide (SiO or SiO₂) and/or silicon oxynitride (SiON), not being limited thereto, and the high-k dielectric layer may be formed of a high-k material such as hafnium oxide (HfO₂), hafnium silicate (HfSiO₄), titanium oxide (TiO₂), zirconium oxide (ZrO₂), aluminum oxide (Al₂O₃), lanthanum oxide (La₂O₃), yttrium oxide (Y₂O₃), etc.

The 1^{st} work-function metal layer LF may formed on the gate dielectric layer GD surrounding the 1^{st} channel layers 110 to control a gate threshold voltage for the 1^{st} transistor T1, and the 2^{nd} work-function metal layer UF may formed on the gate dielectric layer GD surrounding the 2^{nd} channel layers 120 to control a gate threshold voltage for the 2^{nd} transistor T2. Each of the work-function metal layers LF and UF may be formed of metal such as Ti, Ta, Al, W, TiN, WN, TiAl, TiAlN, TaN, TiC, TaC, TiAlC, TaCN, TaSiN, and/or a combination thereof, not being limited thereto. However, the 1^{st} work-function metal layer LF for the 1^{st} transistor T1 and the 2^{nd} work-function metal layer UF for the 2^{nd} transistor T2 may be formed of different materials when the two transistors are of different polarity types, i.e., n-type and p-type, respectively. For example, when the 1^{st} transistor T1 is of n-type and the 2^{nd} transistor T2 is of p-type, the 1^{st} work-function metal layer LF may be formed of Al or TiC, and the 2^{nd} work-function metal layer UF may be formed of TiN.

The 1^{st} work-function metal layer LF may be isolated from the 1^{st} source/drain regions 135 by the gate dielectric layer GD, and the 2^{nd} work-function metal layer UF may be isolated from the 2^{nd} source/drain regions 145 also by the gate dielectric layer GD.

Although the two transistors T1 and T2 have different work-function metal layers LF and UF, respectively, the same gate electrode GE may surround the two work-function metal layers LF and UF to form the two transistors T1 and T2 as a complementary metal-oxide-semiconductor (CMOS) device, e.g., an inverter circuit. The gate electrode GE may be formed of a metal such as Cu, W, Al, Ru, Mo, Co, etc., or a metal alloy thereof. However, the disclosure is not limited thereto, and a gate isolation layer or structure may be formed to separate the gate structure 150 into two gate structures for the respective two transistors T1 and T2. For example, a gate electrode on the 1^{st} work-function metal layer LF may be isolated from a gate electrode on the 2^{nd} work-function metal layer UF.

An interlayer isolation structure 170 may be formed to surround the source/drain regions 135 and 145 to isolate these semiconductor structures from each other and other circuit elements. The interlayer isolation structure 170 may be formed of a low-k dielectric material such as silicon oxide (e.g., SiO₂).

Gate spacers 119 may be respectively formed on a left side surface and a right side surface of an upper portion of the gate structure 150 disposed above the uppermost 2^{nd} channel layer 120 in each of the channel stacks 10A-10C. For example, the gate spacers 119 may be respectively formed on a left side surface and a right side surface of the gate dielectric layer included in the upper portion of the gate structure 150 in each of the channel stacks 10A-10C. Thus, the gate spacers 119 may also laterally face the 2^{nd} source/drain regions 145 and/or a portion of the interlayer isolation structure 170 formed vertically above the 2^{nd} source/drain regions 145.

The gate spacers 119 may be used to protect a dummy gate structure formed of polycrystalline silicon (p-Si) or amorphous silicon (a-Si) from various processes performed in manufacturing the 3D-stacked semiconductor device 10, and remain after the dummy gate structure is replaced by the gate structure 150 to prevent current leakage therefrom to other circuit elements. The gate spacer 119 may be formed of silicon nitride (e.g., SiN or Si₃N₄), SiBCN, SiCN, SiOC, SiOCN, silicon oxide (e.g., SiO₂), etc., not being limited thereto.

As shown in FIGS. 1A and 1C, the 2^{nd} channel structure formed of the 2^{nd} channel layers 120 may have a smaller width in the 2^{nd} direction D2 than the 1^{st} channel structure formed of the 1^{st} channel layers 110, and the 2^{nd} channel lays 120 may only partially overlap the 1^{st} channel layer 110 in the 3^{rd} direction D3. For example, left side surfaces of the channel layers 110 and 120 may be aligned or coplanar with each other in the 3^{rd} direction D3, while right side surfaces thereof are not. Thus, as shown in FIG. 1D, the 2^{nd} source/drain regions 145 epitaxially grown from the 2^{nd} channel layers 120 may also be formed to have a smaller width in the 2^{nd} direction D2 than the 1^{st} source/drain regions 135 epitaxially grown from the 1^{st} channel layers 110, and a right portion of the 1^{st} source/drain region 135 may not be overlapped by the 2^{nd} source/drain region 145 in the 3^{rd} direction D3. This width difference of the source/drain regions provides a free space above a top surface of each of the 1^{st} source/drain regions 135 which is not vertically overlapped by the 2^{nd} source/drain region 145 so that other circuit elements such as a source/drain contact structure may be formed through this space to contact at least a portion of the top surface of the 1^{st} source/drain region 135. The foregoing characteristics of the channel structures and the source/drain regions may be provided to address increasing demands for a high device density in a semiconductor device including the stacked semiconductor device 10.

The 2^{nd} channel structure forming the 2^{nd} transistor T2 may have a greater number of channel layers than that of the 1^{st} channel structure forming the 1^{st} transistor T1 such that the two transistors may have the same or substantially same effective channel width (W_{eff}). For example, the 2^{nd} channel structure may have three channel layers while the 1^{st} channel structure have two channel layers as shown in FIGS. 1B and 1C.

The different channel widths and the different number of channel layers may facilitate optimization of a stacked semiconductor device in terms of not only an area gain for a high-density semiconductor device but also device performance such as current speed, work load distribution, power efficiency, contact resistance, thermal control, structural stability, etc.

Referring back to FIGS. 1B and 1C, the middle isolation structure 130 may include the two middle isolation layers 130L and 130U with the gap layer 130M therebetween which may be formed by replacing respective sacrificial layers in a manufacturing process of the stacked semiconductor device 10. By forming the middle isolation structure 130 with multiple isolation layers, for example, two middle isolation layers 130L and 130U with a gap layer therebetween, the middle isolation structure 130 may be formed to have a greater thickness, for example, a thickness TH1 which is greater than a length LH which is a sum of lengths of two gate spacers 119 and a length of either of the 1^{st} source/drain region 135 and the 2^{nd} source/drain regions 145 in the 1^{st} direction D1. This length LH may be a distance between two adjacent gate structures 150 in the 1^{st} direction D1. For example, the length LH may be a distance between a left side surface of the gate dielectric layer GD included in the upper portion of the gate structure 150 in the 2^{nd} channel stack 10B and a right side surface of the gate dielectric layer GD in the upper portion of the gate structure 150 in the 1^{st} channel stack 10A. This length LH may also be defined by a distance between two adjacent dummy gate structures which are placeholder structures of the gate structures 150 in the process of manufacturing the stacked semiconductor device 10.

The thicker middle isolation structure 130 may improve device performance of the stacked semiconductor device in terms of preventing a short-circuit and parasitic capacitance between the two transistorsT1 and T2 of the stacked semiconductor device 10. Due to the greater thickness of the middle isolation structure 130, the interlayer isolation structure 170 between the 1^{st} source/drain region 135 and the 2^{nd} source/drain region 145 thereabove may also have a greater thickness in the 3^{rd} direction D3 to provide improved isolation performance between the source/drain regions of two transistors T1 and T2.

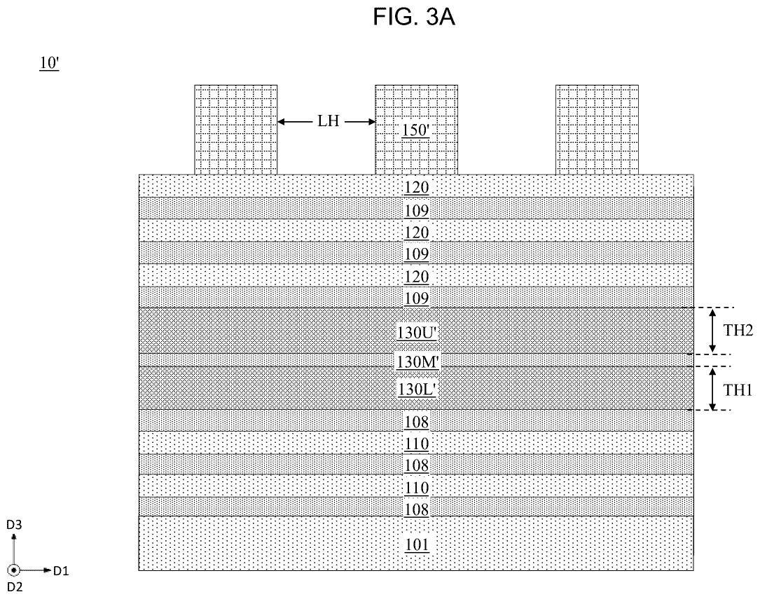

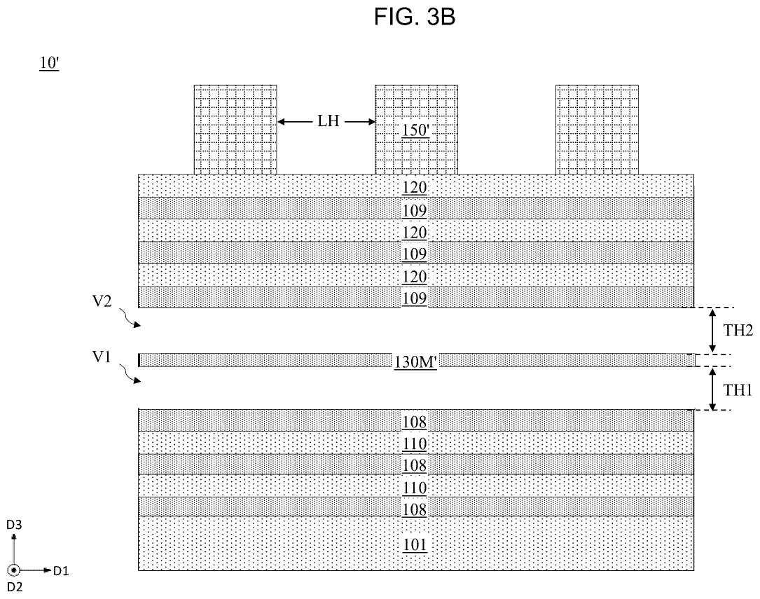

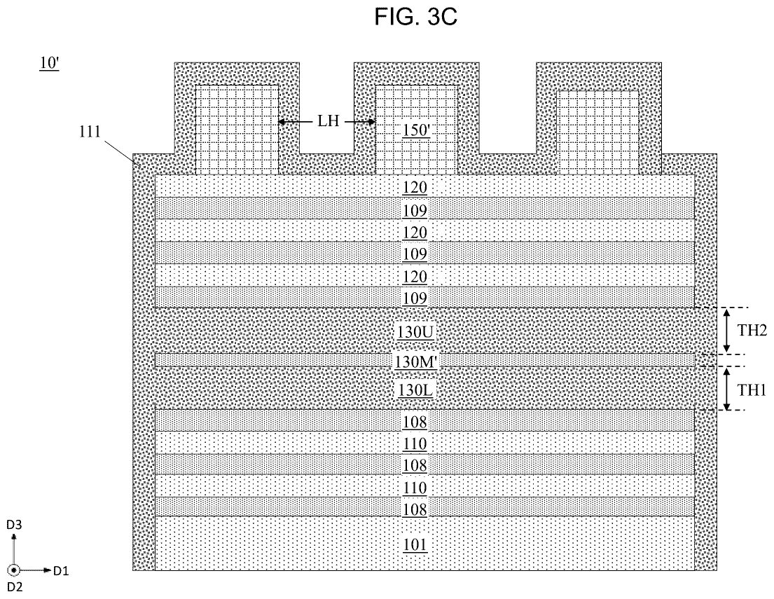

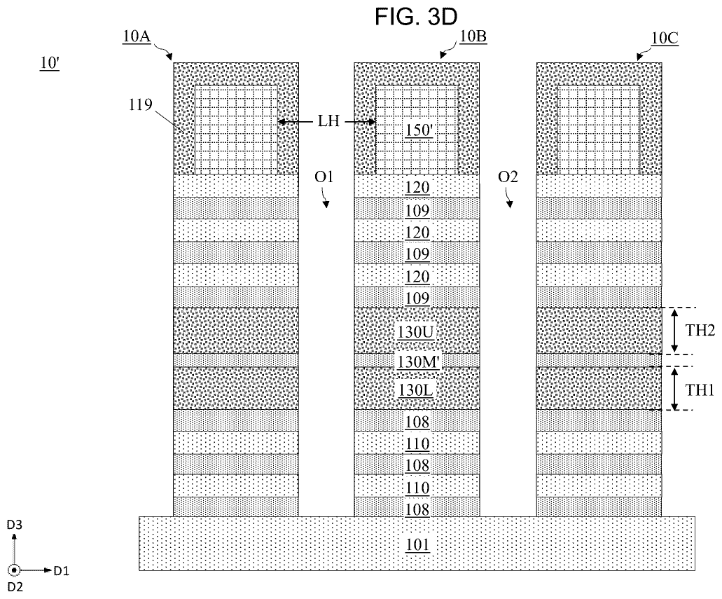

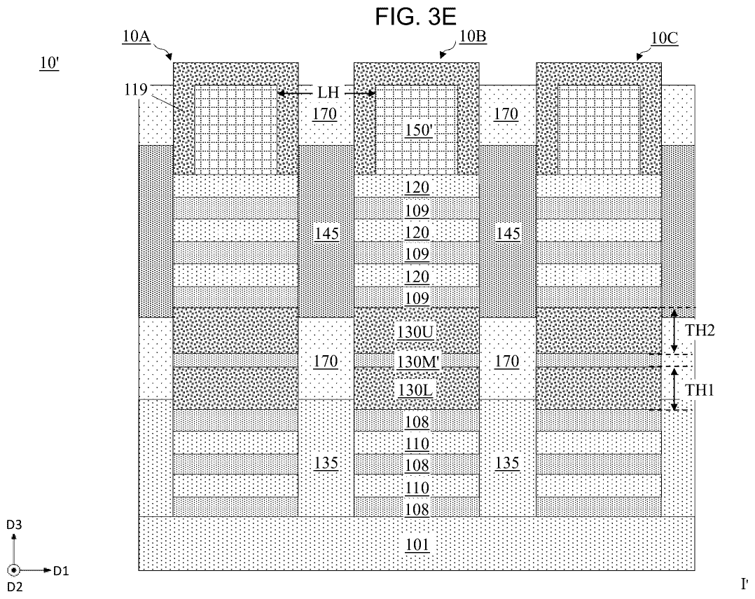

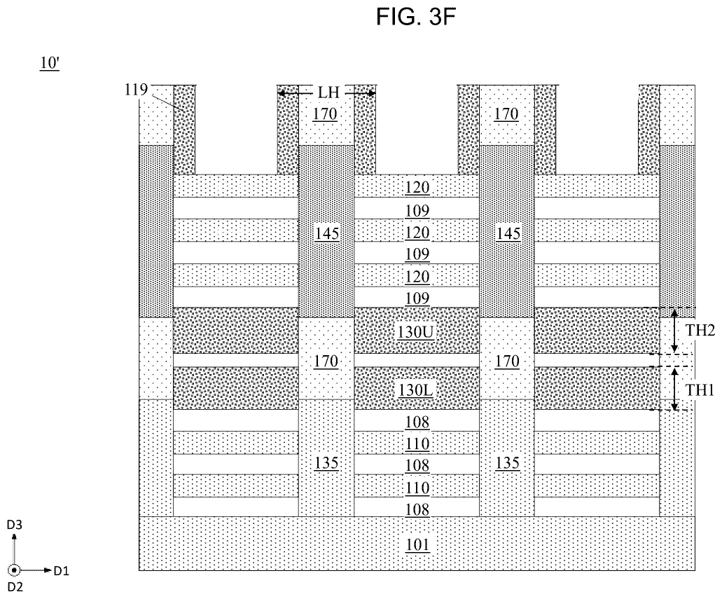

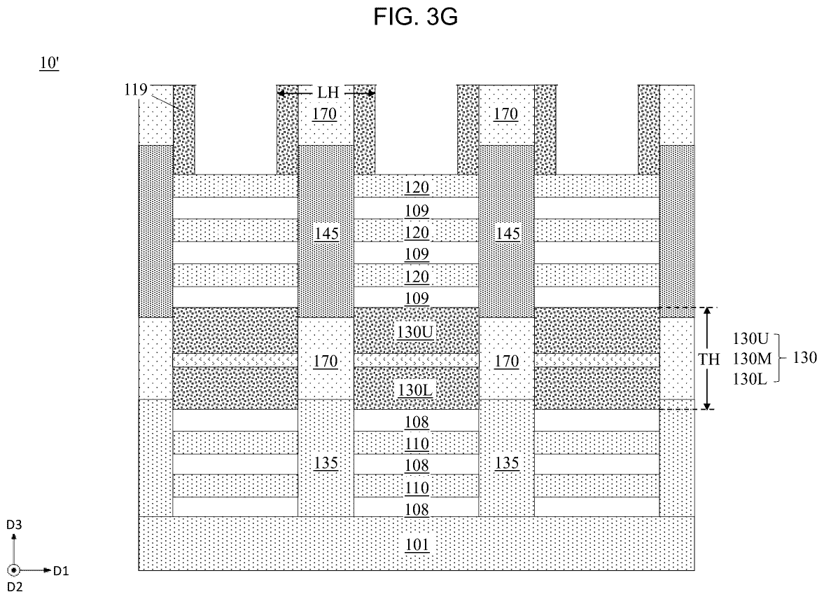

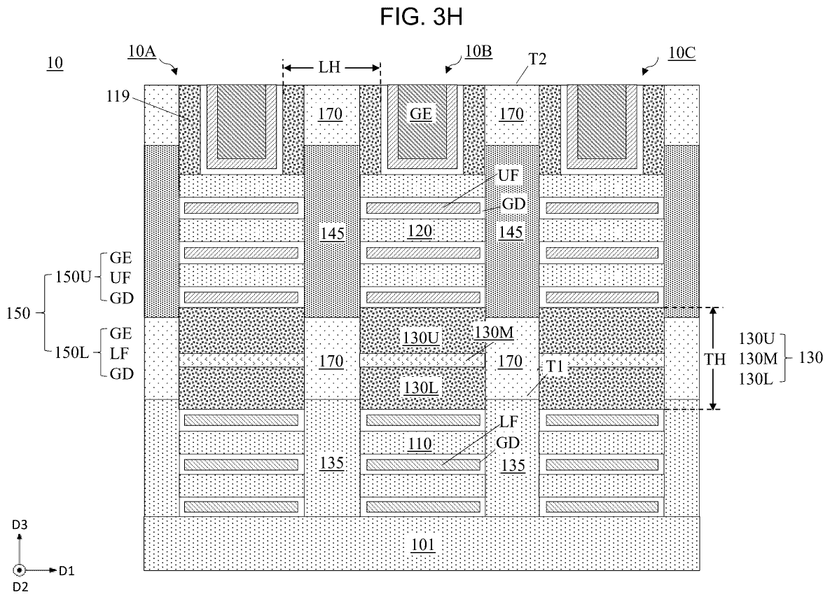

However, the greater thickness of the middle isolation structure 130 may not be achieved through forming a single middle isolation layer to have a greater thickness because a single middle isolation layer cannot be formed to be thicker than a length of an opening to be formed by patterning an initial channel stack to provide a space for forming a source/drain region. This will be described later in reference to FIGS. 3A-3H. Thus, the embodiments of the disclosure provide the stacked semiconductor device 10 including multiple middle isolation layers with at least one gap layer therebetween, for example, the middle isolation layers 130L and 130U with the gap layer 130M therebetween.

The two middle isolation layers 130L and 130U may be formed of the same material forming the gate spacer 119, for example, silicon nitride (e.g., SiN or Si₃N₄), SiBCN, SiCN, SiOC, SiOCN, silicon oxide (e.g., SiO₂), etc., not being limited thereto, as the middle isolation layers 130L and 130U may be formed through the same deposition process along with the gate spacer 119. The gap layer 130M may be formed of the same material forming the middle isolation layers 130L and 130U or a different dielectric material. Additionally or alternatively, the gap layer 130M may be formed of the same material as the high-k dielectric layer of the gate dielectric layer GD of the 1^{st} gate structure 150L and the 2^{nd} gate structure 150U.

In the above embodiments of FIGS. 1A-1D, the gate dielectric layer GD is formed as an isolation structure between the 1^{st} source/drain region 135 and the 1^{st} work-function metal layer LF and between the 2^{nd} source/drain region 145 and the 2^{nd} work-function metal layer UF. However, for this isolation purpose, inner spacers may be formed in the stacked semiconductor device.

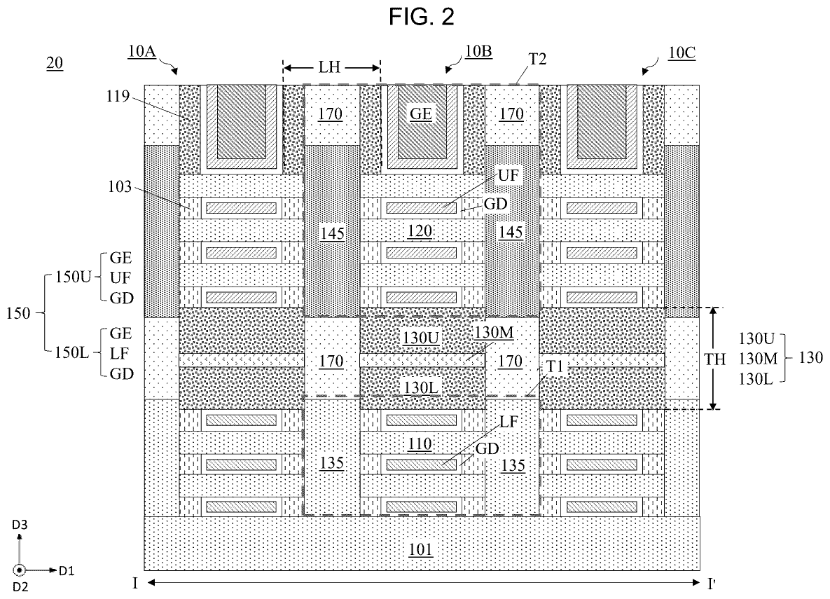

FIG. 2 illustrates a stacked semiconductor device in which multiple middle isolation layers are formed to separate channel structures of two transistors formed at a 1^{st} level and a 2^{nd} level, respectively, and source/drain regions are isolated from a gate structure through inner spacers, according to one or more embodiments.

Referring to FIG. 2, a stacked semiconductor device 20 may include the same structural elements forming the stacked semiconductor device 10 of FIGS. 1A-1D including the middle isolation layers 130L and 130U with the gap layer 130M therebetween. Thus, the duplicate descriptions thereof may be omitted herein. However, the stacked semiconductor device 20 differs from the stacked semiconductor device 10 in that inner spacers 103 may be formed between the 1^{st} source/drain region 135 and the 1^{st} work-function metal layer LF and between the 2^{nd} source/drain region 145 and the 2^{nd} work-function metal layer UF to isolate these structural elements. The inner spacers103 may be formed of silicon nitride (e.g., SiN or Si₃N₄), not being limited thereto. Still, however, the stacked semiconductor device 20 may have multiple middle isolation layers 130L and 130U with the gap layer 130M therebetween to improve device performance as described above.

Herebelow, a method of manufacturing a stacked semiconductor device corresponding to the stacked semiconductor device 10 of FIGS. 1A-1D is provided.

FIGS. 3A-3H illustrate cross-section views of intermediate semiconductor devices after respective steps of manufacturing a stacked semiconductor device in which multiple middle isolation layers are formed to separate channel structures of two transistors formed at a 1^{st} level and a 2^{nd} level, respectively, according to one or more embodiments.

The stacked semiconductor device manufactured through the steps described in reference to FIGS. 3A-3H may be or correspond to the stacked semiconductor device 10 shown in FIGS. 1A-1D. Thus, materials, functions, and structural characteristics of the intermediate semiconductor devices shown in FIGS. 3A-3H may be the same as or similar to those of the stacked semiconductor device 10 of FIGS. 1A-1D, and thus, duplicate descriptions may be omitted herein while the same reference characters or numerals used in reference to FIGS. 1A-1D may be used herebelow. It is also to be understood here that the cross-section views of FIGS. 3A-3H correspond to the cross-section view of the stacked semiconductor device 10 shown in FIG. 1B.

Referring to FIG. 3A, an initial channel stack may be formed by epitaxially growing a plurality of semiconductor layers one by one from a substrate 101. Further, a plurality of dummy gate structures 150′ may be formed on the initial channel stack to provide an intermediate semiconductor device 10′.

The initial channel stack formed on the substrate 101 may include a 1^{st} channel structure formed of 1^{st} sacrificial layers 108 and 1^{st} channel layers 110 vertically stacked in an alternating manner at a 1^{st} level and a 2^{nd} channel structure formed of 2^{nd} sacrificial layers 109 and 2^{nd} channel layers 120 vertically stacked in an alternating manner at a 2^{nd} level. Between the two channel structures may be formed a 1^{st} middle sacrificial layer 130L′, a 2^{nd} middle sacrificial layer 130M′, and a 3^{rd} middle sacrificial layer 130U′ in this order.

While the substrate 101 and the channel layers 110 and 120 may be formed of silicon (Si), the sacrificial layers 108, 130L′, 130M′, 130U′ and 109 may be formed of silicon germanium (SiGe) with respective Ge concentrations therein. The 1^{st} middle sacrificial layer 130L′ and the 3^{rd} middle sacrificial layer 130U′ may have a higher Ge concentration than the 1^{st} sacrificial layers 108, the 2^{nd} middle sacrificial layer 130M′ and the 2^{nd} sacrificial layers 109. For example, the 1^{st} middle sacrificial layer 130L′ and the 3^{rd} middle sacrificial layer 130U′ may have a Ge concentration of 40-45%, and the 1^{st} sacrificial layers 108, the 2^{nd} middle sacrificial layer 130M′ and the 2^{nd} sacrificial layers 109 may have a Ge concentration of 25-30%.

Here, the sacrificial layers 108, 130L′, 109, 130U′ and 109 are referred to as such because these structural elements will be removed and replaced by other layers or structures in a later step (FIG. 3H) of manufacturing a stacked semiconductor device from the intermediate semiconductor device 10′.

The dummy gate structures 150′ may be formed on a top surface of the initial channel stack at positions below which respective channel stacks are to be formed in a later step (FIG. 3D). The dummy gate structures 150′ may be formed by depositing polysilicon (p-Si) or amorphous silicon (a-Si) on the initial channel stack through, for example, physical vapor deposition (PVD), chemical vapor deposition (CVD), plasma enhanced chemical vapor deposition (PECVD), or a combination thereof, to form an initial dummy gate structure, and applying photolithography/masking/etching on the initial dummy gate structure.

A purpose of forming the dummy gate structure 150′ is to protect structural elements formed therebelow from various operations such as deposition and etching performed to form surrounding structures in subsequent steps of manufacturing the stacked semiconductor device. The dummy gate structure 150′ may also serve to define dimensions of the channel layers 110 and 120 of each channel stack formed from the initial channel stack.

In this step, the initial channel stack may be formed such that each of a thickness TH1 of the 1^{st} middle sacrificial layer 130L′ and a thickness TH2 of the 2^{nd} middle sacrificial layer 130U′ in the 3^{rd} direction D3 is not greater than a distance LH between two adjacent dummy gate structures 150′ in the 1^{st} direction. This is because, if either of the thicknesses TH1 and TH2 is greater than the distance LH, a middle isolation layer replacing each of the middle sacrificial layers 130L′ and 130U′ in a later step (FIG. 3C) which is also formed in a space between the two adjacent gate structures 150′ as gate spacers may be folded in this space, which may prevent or adversely affect subsequent steps of manufacturing the stacked semiconductor device. Thus, two or more middle sacrificial layers, for example, two middle sacrificial layers 130L′ and 130U′, having a smaller thickness, for example, the thicknesses TH1 and TH2, may be formed between the 1^{st} channel structure and the 2^{nd} channel structure so that the same number of middle isolation layers replacing the two or more middle sacrificial layers may be formed as a thicker middle isolation structure in a later step (FIG. 3C). As described above in reference to FIGS. 1A-1D, a thicker middle isolation structure may improve device performance of the stacked semiconductor device to be manufactured from the intermediate semiconductor device 10′.

Although each of the thicknesses TH1 and TH2 may be smaller than the distance LH, a sum of these two thicknesses TH1 and TH2 or a sum of these two the thicknesses TH1 and TH2 and a thickness of the 2^{nd} middle sacrificial layer 130M′ which will be replaced by a gap layer in a later step (FIG. 3G) may be greater than the distance LH.

Referring to FIG. 3B, the 1^{st} middle sacrificial layer 130L′ and the 3^{rd} middle sacrificial layer 130U′ may be removed from the initial channel stack to form a 1^{st} void V1 and a 2^{nd} void V2, respectively.

The removal operation in this step may be performed through, for example, dry etching or wet etching using an etchant such as an ammonia-peroxide mixture which removes the 1^{st} middle sacrificial layer 130L′ and the 3^{rd} middle sacrificial layer 130U′ of SiGe with a high Ge concentration while the channel layers 110 and 120 of silicon (Si) and the 1^{st} sacrificial layers 108, the 2^{nd} sacrificial layers 109 and the 2^{nd} middle sacrificial layer 130M′ of SiGe with a low Ge concentration are not or minimally attacked by the etchant.

As a result of the removal of the 1^{st} middle sacrificial layer 130L′ and the 3^{rd} middle sacrificial layer 130U′, the 1^{st} void V1 and the 2^{nd} void V2 may be respectively formed with the 2^{nd} middle sacrificial layer 130M′ therebetween. The voids V1 and V2 may also have the thicknesses TH1 and TH2 in the 3^{rd} direction D3.

Referring to FIG. 3C, an isolation layer 111 may be formed to surround the initial channel stack with the dummy gate structures 150′ thereon and also fill in the two voids V1 and V2 provided by the removal of the 1^{st} middle sacrificial layer 130L′ and the 3^{rd} middle sacrificial layer 130U′ in the previous step (FIG. 3B).

The formation of the isolation layer 111 may be performed through, for example, depositing silicon nitride (e.g., SiN or Si₃N₄), SiBCN, SiCN, SiOC, SiOCN, or silicon oxide (e.g., SiO₂), not being limited thereto, on an outer surface of the intermediate semiconductor device 10′ and in the voids V1 and V2 obtained in the previous step (FIG. 3B). The deposition used in this step may be atomic layer deposition (ALD), PVD, CVD, PECVD, plasma enhanced ALD (PEALD) or a combination thereof.

Thus, the voids V1 and V2 formed in the previous step may be filled in with the isolation layer 111. Further, the isolation layer 111 may be layered on top surfaces of the initial channel stack which may be a top surface of the uppermost 2^{nd} channel layer 120 exposed between the dummy gate structures 150′, top surfaces and side surfaces of the dummy gate structures 150′.

As described earlier in reference to FIG. 3A, the voids V1 and V2 obtained in the previous step (FIG. 3B) may have the respective thicknesses TH1 and TH2 each of which is smaller than the distance LH between the two adjacent dummy gate structures 150′ in the 1^{st} direction D1. Thus, the isolation layer 111 filled in each of the voids V1 and V2 may not be folded in the space between the two adjacent dummy gate structures 150′ in the 1^{st} direction D1.

Referring to FIG. 3D, the initial channel stack with the isolation layer 111 may be patterned based on portions of the isolation layer 111 formed on the top surfaces and the side surfaces of the dummy gate structures 150′.

The patterning operation in this step may be performed through, for example, dry etching such as reactive ion etching based on the portions of the isolation layer 111 formed on the top surfaces and the side surfaces of the dummy gate structures 150′ and respective hard mask patterns formed thereon.

By the patterning operation in this step, a 1^{st} channel stack 10A, a 2^{nd} channel stack 10B and a 3^{rd} channel stack 10C may be formed on the substrate 101 with openings O1 and O2 therebetween, and a top surface of the substrate 101 may be exposed through the openings O1 and O2. Further, the isolation layer 111 formed in the voids V1 and V2 in the previous step may also be patterned to form a 1^{st} middle isolation layer 130L and a 2^{nd} middle isolation layer 130U, respectively, with the 2^{nd} middle sacrificial layer 130M′ therebetween in each of the channel stacks 10A-10C. In addition, the isolation layer 111 formed on the top surface and the side surfaces of each of the dummy gate structure 150′ may form a gate spacer 119.

Thus, each of the channel stacks 10A-10C may include a 1^{st} channel structure including the 1^{st} sacrificial layers 108 and the 1^{st} channel layers 110, the 1^{st} middle isolation layer 130L, the 2^{nd} middle sacrificial layer 130M′, the 2^{nd} middle isolation layer 130U, a 2^{nd} channel structure including the 2^{nd} sacrificial layers 109 and the 2^{nd} channel layers 120, a dummy gate structure 150′ with the isolation layer 111 on a top surface and side surfaces thereof.

In each of the openings O1 and O2, side surfaces of the gate spacer 119, the channel layers 110, 120, the sacrificial layers 108, 109, 130M′, and the middle isolation layers 130L, 130U of each of the channel stacks 10A-10C may be exposed and vertically aligned or coplanar.

Referring to FIGS. 3E, 1^{st} source/drain regions 135 and 2^{nd} source/drain regions 145 may be formed in the openings O1 and O2 based on the 1^{st} channel layers 110 and the 2^{nd} channel layers 120, respectively.

The 1^{st} source/drain regions 135 may be epitaxially grown from the 1^{st} channel layers 110 through, for example, molecular beam epitaxy (MBE), vapor-phase epitaxy (VPE), etc., not being limited thereto. The 1^{st} source/drain regions 135 may be formed of silicon (Si) and may be doped in-situ with impurities such as phosphorus (P), arsenic (As), antimony (Sb), etc., so that the 1^{st} source/drain region 135 can be of an n-type. Alternatively, the 1^{st} source/drain regions 135 may be formed of silicon germanium (SiGe) and may be doped in-situ with impurities such as boron (B), gallium (Ga), indium (In), etc., so that the 1^{st} source/drain regions 135 can be of a p-type.

After formation of the 1^{st} source/drain regions 135, an interlayer isolation structure 170 may be formed above the 1^{st} source/drain regions 135 to isolate the 1^{st} source/drain regions 135 from other circuit elements. The interlayer isolation structure 170 may be formed of a low-k dielectric material such as silicon oxide (e.g., SiO₂).

The 2^{nd} source/drain regions 145 may be epitaxially grown from the 2^{nd} channel layers 120 through, for example, MBE, VPE, etc., not being limited thereto. The 2^{nd} source/drain regions 145 may be formed of silicon (Si) and may be doped in-situ with impurities such as P, As, Sb, etc., so that the 2^{nd} source/drain regions 145 can be of an n-type. Alternatively, the 2^{nd} source/drain regions 145 may be formed of SiGe and may be doped in-situ with impurities such as B, Ga, In, etc., so that the 2^{nd} source/drain regions 145 can be of a p-type.

After forming the 2^{nd} source/drain regions 145, an additional interlayer isolation structure 170 may be formed on the 2^{nd} source/drain regions 145.

As the source/drain regions 135 and 145 are formed with the interlayer isolation structure 170 in the openings O1 and O2, the distance LH between two adjacent dummy gate structures 150′ may be a sum of lengths of two gate spacers 119 facing each other with the interlayer isolation structure 170 and/or the 2^{nd} source/drain region 145 therebetween and a length of the 2^{nd} source/drain region 145 (or the interlayer isolation structure 170) in the 1^{st} direction D1.

Referring to FIG. 3F, the dummy gate structures 150′, the 1^{st} sacrificial layers 108, the 2^{nd} middle sacrificial layers 130M′ and the 2^{nd} sacrificial layers 109 may be removed through, for example, dry etching, wet etching, or a combination thereof, not being limited thereto, using an etchant, for example, as a mixture of nitric acid (HNO₃) and hydrofluoric acid (HF), not being limited thereto.

In this step, a portion of the gate spacer 119 formed on the top surface of each of the dummy gate structures 150′ may be first removed by dry etching or wet etching to expose the dummy gate structure 150′.

Referring to FIG. 3G, a space formed by the removal of the 2^{nd} middle sacrificial layer 130M′ may be filled in with a gap layer 130M formed of an isolation material such as silicon nitride (e.g., SiN or Si₃N₄), SiBCN, SiCN, SiOC, SiOCN, or silicon oxide (e.g., SiO₂), not being limited thereto, which may be the same as or different from the material forming the middle isolation layers 130L and 130U. The formation of the gap layer 130M may be performed through, for example, ALD, PEALD, PECVD, etc., not being limited thereto.

As the gap layer 130M is formed in this step, a middle isolation structure 130 including the 1^{st} middle isolation layer 130L, the gap layer 130M and the 2^{nd} middle isolation layer 130U stacked in this order between two channel structures may be formed. A thickness TH of the middle isolation structure 130 may be greater than the distance or length LH.

As the gap layer 130M is formed at a step different from the step in which the two middle isolation layers 130L and 130U are formed, an interface, junction, barrier, or a connection surface may be formed between the gap layer 130M and each of the two middle isolation layers 130L and 130U.

Referring to FIG. 3H, the spaces formed by the removal of the dummy gate structures 150′, the 1^{st} sacrificial layers 108 and the 2^{nd} sacrificial layers 109 may be filled in with the gate structure 150 to finish the intermediate semiconductor device 10′ as a stacked semiconductor device 10.

A gate dielectric layer GD may be first formed on the 1^{st} channel layers 110 and the 2^{nd} channel layers 120 in the space formed by the removal of the 1^{st} sacrificial layers 108 and the 2^{nd} sacrificial layers 109, followed by formation of a 1^{st} work-function metal layer LF and a 2^{nd} work-function metal layer UF, respectively, and then formation of a gate electrode GE.

The gate dielectric layer GD may include an interfacial layer which may be formed on an outer surface of each of the channel layers 110 and 120 through, for example, thermal oxidation or annealing of the channel layers 110 and 120. After the interfacial layer is formed on the channel layers 110 and 120, a high-k dielectric layer may be formed through, for example, CVD, ALD, PEALD, etc. or a combination thereof, not being limited thereto, on the interfacial layer. The interfacial layer may be formed of an oxide material such as silicon oxide (SiO or SiO₂) and/or silicon oxynitride (SiON), not being limited thereto, and the high-k dielectric layer may include a high-k material such as hafnium oxide (HfO₂), hafnium silicate (HfSiO₄), titanium oxide (TiO₂), zirconium oxide (ZrO₂), aluminum oxide (Al₂O₃), lanthanum oxide (La₂O₃), yttrium oxide (Y₂O₃), etc.

In a case where the gap layer 130M is not separately formed in the previous step (FIG. 3G), the high-k dielectric layer may be formed in the space formed by the removal of the 2^{nd} middle sacrificial layer 130M′ in this step.

The work-function metal layers LF and UF may be formed to surround the gate dielectric layer on the channel layers 110 and 120, respectively, through, for example, CVD, ALD, PECVD, PEALD, or a combination thereof of a metal such as Ti, Ta, Al, W, TiN, WN, TiAl, TiAlN, TaN, TiC, TaC, TiAlC, TaCN, TaSiN, and/or a combination thereof, not being limited thereto. The gate electrode GE may be formed on the work-function metal layers LF and UF through, for example, CVD, PVD, PECVD, etc., or a combination thereof of a metal such as Cu, W, Al, Ru, Mo, Co, etc., or a metal alloy thereof.

By forming the gate structure 150, the stacked semiconductor device 10 may include the 1^{st} channel structure and the 2^{nd} channel structure surrounded by the gate structure 150 and isolated from each other though the multiple isolation layers 130L and 130U with the gap layer 130M therebetween.

The above-described embodiments are directed to a stacked semiconductor device in which two middle isolation layers with one gap layer therebetween are formed as a middle isolation structure between two channel structures each of which is formed of nanosheet channel layers. However, the disclosure is not limited thereto. According to one or more other embodiments, three or more middle isolation layers with gap layers therebetween may be formed as a middle isolation structure in a stacked semiconductor device for the same channel structure isolation purposes. However, even in these embodiments, each of the middle isolation layers may be formed to have a thickness which is smaller than a distance between two adjacent dummy gate structures to avoid isolation layer folding described in reference to FIGS. 3A-3H. Still, however, a sum of thicknesses of the middle isolation layers with the gap layers therebetween may be greater than the distance between the two adjacent dummy gate structures.

The above-described embodiments are directed to a stacked semiconductor device in which each of two stacked transistors is a nanosheet transistor. However, the disclosure is not limited thereto. According to one or more other embodiments, each of the two stacked transistors may be a different type of field-effect transistor such as FinFET or forksheet transistor.

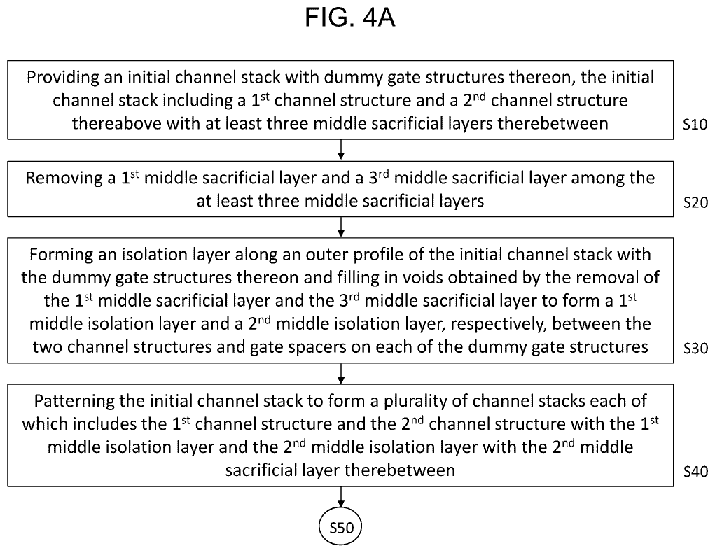

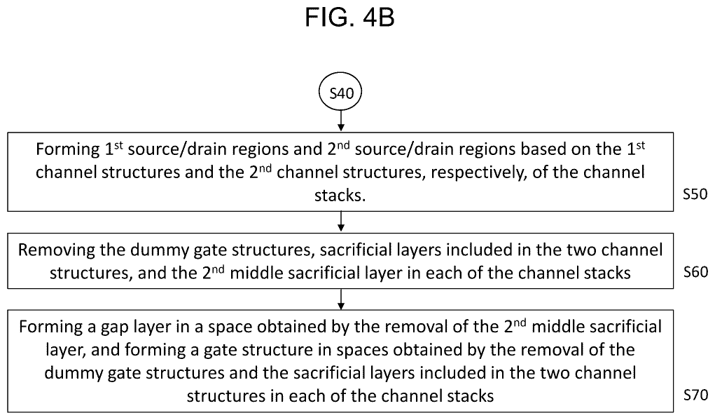

FIGS. 4A and 4B illustrate a flowchart of a method of manufacturing a stacked semiconductor device in which multiple middle isolation layers are formed to separate channel structures of two transistors formed at a 1^{st} level and a 2^{nd} level, respectively, according to one or more other embodiments.

The semiconductor device manufactured according to the flowchart of FIGS. 4A and 4B may be the same as or correspond to the stacked semiconductor device 10 shown in FIGS. 1A-1D, and operations performed for each step of manufacturing the stacked semiconductor device may be the same as or similar to those described above in reference to FIGS. 3A-3H. Thus, duplicate descriptions may be omitted herein.

In step S10, an initial channel stack with a plurality of dummy gate structures thereon is provided. The initial channel stack may include a 1^{st} channel structure at a 1^{st} level and a 2^{nd} channel structure at a 2^{nd} level with at least three middle sacrificial layers therebetween.

The 1^{st} channel structure may include 1^{st} sacrificial layers and 1^{st} channel layers alternatingly stacked in a vertical direction, and the 2^{nd} channel structure may include 2^{nd} sacrificial layers and 2^{nd} channel layers also alternatingly stacked in the vertical direction. The at least three middle sacrificial layers between the two channel structures may include a 1^{st} middle sacrificial layer, a 2^{nd} middle sacrificial layer, and a 3^{rd} middle sacrificial layer in this order from a top surface of the 1^{st} channel structure, which may be a top surface of the uppermost 1^{st} sacrificial layer. The channel layers included in the two channel structures may be formed of silicon (Si) while the sacrificial layers included in the two channel structures and the middle sacrificial layers may all be formed of silicon germanium (SiGe). However, the 1^{st} middle sacrificial layer and the 3^{rd} middle sacrificial layer may have a higher Ge concentration than the other sacrificial layers including the 2^{nd} middle sacrificial layer.

The initial channel stack may be formed through epitaxial growth of the plurality of semiconductor layers from a Si-based substrate. The epitaxial growth may be performed such that a thickness of each of the 1^{st} middle sacrificial layer and the 3^{rd} middle sacrificial layer in the 3^{rd} direction D3 is smaller than a distance between two adjacent dummy gate structures in the 1^{st} direction D1.

In step S20, the 1^{st} middle sacrificial layer and the 3^{rd} middle sacrificial layer may be removed through, for example, dry etching or wet etching using an etchant selectively removing these two sacrificial layers of a higher Ge concentration against the rest of the sacrificial layers of a lower Ge concentration and the channel layers of Si.

In step S30, an isolation layer may be formed along an outer profile of the initial channel stack with the dummy gate structures thereon and may fill in voids obtained by the removal of the 1^{st} middle sacrificial layer and the 3^{rd} middle sacrificial layer to form a 1^{st} middle isolation layer and a 2^{nd} middle isolation layer, respectively, between the two channel structures and gate spacers on each of the dummy gate structures.

While the isolation layer filling in each void may also be formed in a space between two adjacent dummy gate structures, this isolation layer may be folded in this space if a thickness of the isolation layer, which is the same as the thickness of the 1^{st} middle sacrificial layer or the 3^{rd} middle sacrificial layer, is greater than the distance between two adjacent dummy gate structures. The isolation layer folding between two adjacent dummy gate structures may prevent or adversely affect subsequent operations of manufacturing a stacked semiconductor device. Since, however, the thickness of the isolation layer in each of the voids may be smaller than the distance between two adjacent dummy gate structures, the isolation layer folding may be prevented.

Portion of the isolation layer filled in the two voids may form the 1^{st} middle isolation layer and the 2^{nd} middle isolation layer, and portions of the isolation layer on side surfaces and a top surface of each dummy gate structure may form the gate spacers. The isolation layer formed in this step may be silicon nitride (e.g., SiN or Si₃N₄), SiBCN, SiCN, SiOC, SiOCN, silicon oxide (e.g., SiO₂), etc., not being limited thereto.

In step S40, the initial channel stack may be patterned based on the dummy gate structures with the isolation layer thereon to form a plurality of channel stacks so that each of the channel stacks includes the 1^{st} channel structure and the 2^{nd} channel structure with the 1^{st} middle isolation layer and the 2^{nd} middle isolation layer with the 2^{nd} middle sacrificial layer therebetween.

As the initial channel stack is patterned, an opening may be formed between two adjacent channel stacks to expose a top surface of the substrate. The openings may also expose side surfaces of the channel layers and the sacrificial layers as well as the middle isolation layers forming each of the channel stacks.

In step S50, 1^{st} source/drain regions and 2^{nd} source/drain regions may be formed in the openings obtained in the previous step based on the 1^{st} channel structures and the 2^{nd} channel structures, respectively, of the channel stacks. Further, an interlayer isolation structure may be formed to surround the 1^{st} source/drain regions and the 2^{nd} source/drain regions.

In step S60, the dummy gate structures, the sacrificial layers included in the two channel structures, and the 2^{nd} middle sacrificial layer in each of the channel stacks may be removed. At this time a portion of the gate spacers on a top surface of each of the dummy gate structures may also be removed.

In step S70, a gap layer may be formed in a space obtained by the removal of the 2^{nd} middle sacrificial layer, and a gate structure may be formed to fill in spaces obtained by the removal of the dummy gate structures and the sacrificial layers included in the two channel structures in each of the channel stacks.

The gap layer may be formed of an isolation material having a material composition which may be the same as or different from that of the middle isolation layers.

The gate structure may include a gate dielectric layer on each of the channel layers in the two channel structures, a 1^{st} work-function metal layer replacing the 1^{st} sacrificial layers and surrounding the gate dielectric layer on the 1^{st} channel layers, a 2^{nd} work-function metal layer replacing the 2^{nd} sacrificial layers and surrounding the gate dielectric layer on the 2^{nd} channel layers, and a gate electrode surrounding the work-function metal layers.

In a case where the space formed by the removal of the 2^{nd} middle sacrificial layer is not filled in with an isolation material having a material composition which may be the same as or different from that of the middle isolation layers, a high-k dielectric layer forming the gate dielectric layer may be formed in the space to form the gap layer.

Through the above-described steps, a stacked semiconductor device may be manufactured to include a middle isolation structure formed of at least two middle isolation layers and at least one gap layer therebetween.

According to one or more other embodiments, the number of the at least three middle sacrificial layers included in the initial channel stack may be an odd number different from three, for example, five, not being limited thereto. When 1^{st} to 5^{th} middle sacrificial layers are formed between the two channel structures, a 1^{st} middle sacrificial layer, a 3^{rd} middle sacrificial layer, and a 5^{th} middle sacrificial layer may have a higher Ge concentration than the rest of the sacrificial layers in the initial channel stack. In this case, three middle isolation layers may be formed as a middle isolation structure with two gap layers which are alternatively stacked, for example, a 1^{st} middle isolation layer, a 1^{st} gap layer, a 2^{nd} middle isolation layer, a 2^{nd} gap layer, and a 3^{rd} middle isolation layer.

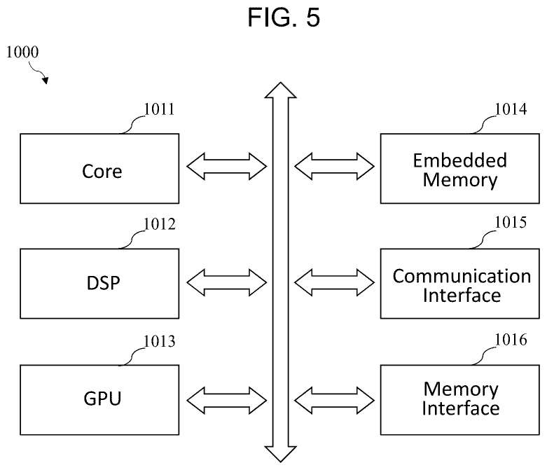

FIG. 5 is a schematic block diagram illustrating an electronic device including a stacked semiconductor device in which multiple middle isolation layers are formed to separate channel structures of two transistors formed at a 1^{st} level and a 2^{nd} level, respectively, according to one or more embodiments. This stacked semiconductor device may be or correspond to the stacked semiconductor device 10 shown in FIGS. 1A-1D or the stacked semiconductor device 20 shown in FIG. 2.

Referring to FIG. 5, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (RAM) (DRAM), a flash memory, etc.

At least one of the core 1011, the DSP 1012, the GPU 1013, and/or the embedded memory 1014 may include the stacked semiconductor device 10 or 20 shown in FIGS. 1A-1D and 2.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A semiconductor device comprising:
a 1^{st} channel structure;
a 2^{nd} channel structure vertically above the 1^{st} channel structure; and
a middle isolation structure comprising a plurality of middle isolation layers between the 1^{st} channel structure and the 2^{nd} channel structure,
wherein the plurality of middle isolation layers are separated in a vertical direction.

2. The semiconductor device of claim 1, wherein the middle isolation structure comprises a 1^{st} middle isolation layer, a 2^{nd} middle isolation layer, and a gap layer between the 1^{st} middle isolation layer and the 2^{nd} middle isolation layer.

3. The semiconductor device of claim 2, wherein the gap layer has a material composition different from a material composition of the 1^{st} middle isolation layer or the 2^{nd} middle isolation layer.

4. The semiconductor device of claim 2, wherein the 1^{st} middle isolation layer or the 2^{nd} middle isolation layer comprises at least one of silicon nitride, SiBCN, SiCN, SiOC, SiOCN, and silicon oxide, and
wherein the gap layer comprises at least one of silicon nitride, SiBCN, SiCN, SiOC, SiOCN, and silicon oxide.

5. The semiconductor device of claim 2, wherein the gap layer and the 1^{st} middle isolation layer or the 2^{nd} middle isolation layer have a same material composition.

6. The semiconductor device of claim 2, wherein the gap layer comprises a high-k dielectric layer.

7. The semiconductor device of claim 1, further comprising:
a source/drain pattern on at least one of the 1^{st} channel structure and the 2^{nd} channel structure;
a gate structure on at least one of the 1^{st} channel structure and the 2^{nd} channel structure; and
gate spacers on side surfaces of an upper portion of the gate structure above the 2^{nd} channel structure,
wherein a thickness of each of the plurality of middle isolation layers in a vertical direction is smaller than a sum of lengths of the gate spacers and a length of the source/drain pattern in a channel-length direction.

8. The semiconductor device of claim 7, wherein a sum of thicknesses of the plurality of middle isolation layers in the vertical direction is greater than the sum of lengths of the gate spacers and a length of the source/drain pattern in a channel-length direction.

9. The semiconductor device of claim 1, further comprising:
a 1^{st} source/drain regions on the 1^{st} channel structure;
a 2^{nd} source/drain regions on the 2^{nd} channel structure;
an interlayer isolation structure vertically above the 2^{nd} source/drain region;
a 1^{st} gate structure on the 2^{nd} channel structure; and
a 1^{st} gate spacer on the 1^{st} gate structure,
wherein a thickness of each of the middle isolation layers in the vertical direction is smaller than a length between a side surface of the 1^{st} gate spacer facing the interlayer isolation structure or the 2^{nd} source/drain region and a side surface of a 2^{nd} gate spacer of a 2^{nd} gate structure adjacent to the 1^{st} gate structure facing the interlayer isolation structure or the 2^{nd} source/drain region.

10. The semiconductor device of claim 9, wherein a thickness of the middle isolation structure in the vertical direction is greater than the length between the side surface of the 1^{st} gate spacer and the side surface of the 2^{nd} gate spacer.

11. A semiconductor device comprising:
a 1^{st} channel structure;
a 2^{nd} channel structure vertically above the 1^{st} channel structure;
a plurality of gate structures; and
a middle isolation structure having a thickness in a vertical direction which is greater than a length between two adjacent gate structures in a channel-length direction, the plurality of gate structures being a replacement of a plurality of dummy gate structures.

12. The semiconductor device of claim 11, wherein the middle isolation structure comprises at least two middle isolation layers with at least one gap layer therebetween in the vertical direction.

13. The semiconductor device of claim 12, wherein a thickness of each of the at least two middle isolation layers in the vertical direction is smaller than the length.

14. The semiconductor device of claim 12, wherein a gate structure among the plurality of gate structures comprises a gate dielectric layer comprising an interfacial layer on the 1^{st} channel structure or the 2^{nd} channel structure and a high-k dielectric layer on the interfacial layer, and
wherein the at least one gap layer and the high-k layer have a same material composition.

15. The semiconductor device of claim 12, wherein the at least two middle isolation layers and the at least one gap layer have a same material composition.

16. The semiconductor device of claim 11, further comprising an interlayer isolation structure at a lateral side of the middle isolation structure.

17. A method of manufacturing a semiconductor device, the method comprising:
forming a 1^{st} channel structure;
forming a 2^{nd} channel structure vertically above the 1^{st} channel structure; and
forming a middle isolation structure comprising a plurality of middle isolation layers between the 1^{st} channel structure and the 2^{nd} channel structure,
wherein the plurality of middle isolation layers are formed to be separated in a vertical direction.

18. The method of claim 17, wherein the middle isolation structure comprises a 1^{st} middle isolation layer, a 2^{nd} middle isolation layer, and a gap layer between the 1^{st} middle isolation layer and the 2^{nd} middle isolation layer.

19. The method of claim 18, further comprising:
forming a plurality of dummy gate structures on an initial channel stack from which the 1^{st} channel structure and the 2^{nd} channel structure are formed; and
forming a plurality of gate structures replacing the plurality of dummy gate structures, respectively,
wherein the 1^{st} channel structure and the 2^{nd} channel structure are formed such that a thickness of the 1^{st} middle isolation layer or the 2^{nd} middle isolation layer in a vertical direction is greater than a length between two adjacent dummy gate structures.

20. The method of claim 19, wherein the gap layer and a high-k layer included in the plurality of gate structures have a same material composition.
